(19) United States
(12) Patent Application Publication
(10) Pub. No.: US 2026/0262553 A1
(43) Pub. Date: Sep. 3, 2026

(54) FLIP CHIP DIE WITH HIGH-DENSITY BUMP TRACE DESIGN

(71) Applicant: Sandisk Technologies, Inc., Milpitas, CA (US)

(72) Inventors: Mengjingzi Zong, Shanghai (CN); Meiqin Hao, Shanghai (CN); Cheng-Hsiung Yang, Hsinghu City (TW); Yuying Chen, Shanghai (CN)

(21) Appl. No.: 19/067,316

(22) Filed: Feb. 28, 2025

(51) Int. Cl. H01L 23/498; H01L 23/00

(52) U.S. Cl. CPC H10W 90/701; H10W 70/65; H10W 72/072; H10W 72/07236

(57) ABSTRACT

A flip chip die with a high-density bump trace design. In one example, a flip chip die package may include a substrate, a flip chip die, a non-linear trace formed on the substrate, and a plurality of solder bumps attached to a bottom surface of the flip chip die. A combined area of the solder bumps is greater than 14.4% of a die area of the flip chip die, and a set of two or more of the solder bumps are electrically connected to the non-linear trace.

### BACKGROUND

The present disclosure relates to integrated circuit devices. More particularly, the present disclosure relates to a flip chip die with a high-density bump trace design.

The capacity and speed of memory arrangements in data storage devices, such as solid state drives (SSDs), is continually improving as technology advances. Demand for higher processing speeds requires increased throughput of memory arrangements. As such, manufacturers of storage devices seek to increase both storage capacity and data throughput for their devices. While it is desirable to increase storage capacity of memory arrangements, the increase in the number of flip chip bumps also increases the likelihood of issues with solder bridges formed between the flip chip bumps.

### SUMMARY

An electronic device, such as a data storage device, and methods of assembling the electronic device include electrically connecting an individual silicon die at a contact pad surface to a controller die or other electrical circuitry on a printed circuit board (PCB). In some examples, the electrical connections between components of the individual silicon die and the electrical circuitry includes electrically conductive traces between flip chip die bumps.

There are two elements that affect a trace. First, as flip chip die bump density increases, and the surface area of the flip chip die remains the same, then the distance between flip chip die bumps must decrease (referred to herein as a “high density bumps”). When the distance between flip chip die bumps decreases, then there is an increase in the likelihood of solder bridges due to challenges with solder flowing properly between shorter and shorter distances. Additionally or alternatively, when the solder flow to a neighbor trace is too heavy, the reliability of the current trace will be reduced due to a lack of solder for the current trace relative to the neighbor trace.

Second, as a die gets thinner, die warpage along the cry direction (i.e., the view of the die from the side) gets worse. Therefore, there is a need for a bump trace die that mitigates the decrease in distance between flip chip die bumps in a flip chip die with high bump density.

In some aspects, the disclosure includes a flip chip die package including: a substrate; a flip chip die mounted on the substrate; a non-linear trace formed on the substrate; and a plurality of solder bumps attached to a bottom surface of the flip chip die. A combined area of the plurality of solder bumps is greater than 14.4% of a die area of the flip chip die, and a set of two or more of the plurality of solder bumps are electrically connected to the non-linear trace.

In some aspects, the disclosure includes a method of manufacturing a flip chip die package. The method includes forming a non-linear trace on a substrate. The method includes depositing a plurality of solder bumps on bottom surface of a flip chip die. The method also includes mounting the flip chip die on the substrate. A combined area of the plurality of solder bumps is greater than 14.4% of a die area of the flip chip die, and two or more of the plurality of solder bumps are electrically connected to the non-linear trace.

In this manner, various aspects of the disclosure provide for improvements in at least the technical fields of memory devices and their design and architecture. The foregoing summary is intended solely to give a general idea of various aspects of the disclosure, and does not limit the scope of the disclosure in any way. Other aspects of the disclosure will become apparent by consideration of the detailed description, the claims, the Abstract, and the accompanying drawings.

### BRIEF DESCRIPTION OF THE DRAWINGS

FIG. 1 is a block diagram illustrating a data storage system, according to embodiments described herein.

FIG. 2 is a diagram illustrating comparative straight-line traces and comparative T-shaped traces on a substrate.

FIG. 3 is a diagram illustrating first and second portions and of normal high density solder bumps corresponding to the comparative straight-line traces and the comparative T-shaped traces of FIG. 2, respectively.

FIG. 4 is a diagram illustrating a first example of a solder failure of the comparative straight-line traces of FIG. 2.

FIG. 5 is a diagram illustrating a second example of a solder failure of the comparative T-shaped traces of FIG. 2.

FIG. 6 is a diagram illustrating an example of a V-shaped trace, according to various aspects of the present disclosure.

FIG. 7 is a diagram illustrating an example of a Y-shaped trace, according to various aspects of the present disclosure.

FIG. 8 is a flowchart illustrating a method of assembling a flip chip die package, according to various aspects of the present disclosure.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. For example, although this disclosure describes technical details for storage devices, it will be understood by those of skill in the art that a storage device is used as an example for describing technology that is applicable to other types of electronic devices that included flip-chip circuits. It also will be understood by those of skill in the art that the drawings are not to scale, where some features are exaggerated in order to highlight such features.

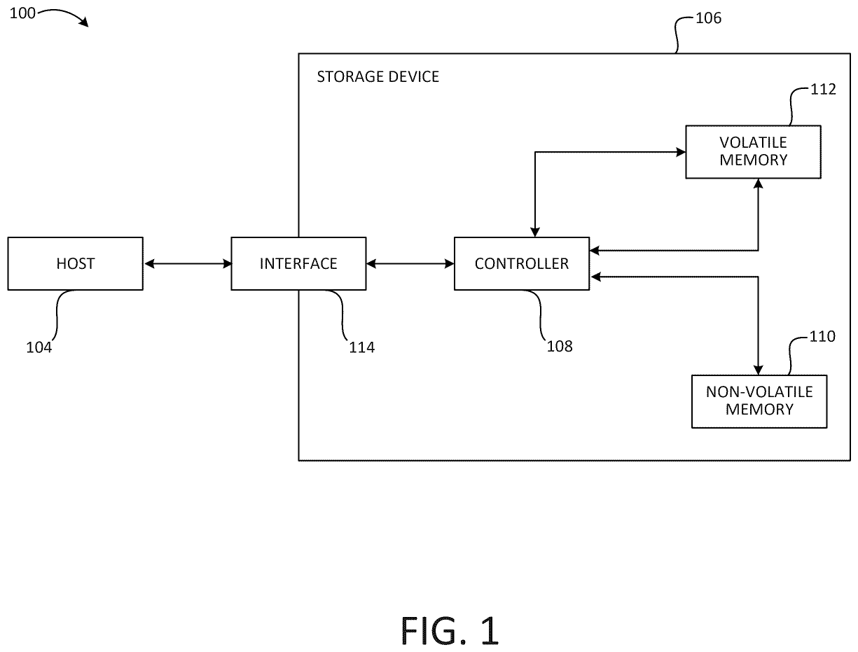

FIG. 1 is a block diagram illustrating a storage system 100 with a storage device 106 that may function in conjunction with a host device 104, in accordance with one or more techniques of this disclosure. For instance, the host device 104 may utilize non-volatile memory devices included in storage device 106 to store and retrieve data.

The storage system 100 includes the host device 104 that may store and/or retrieve data to and/or from the storage device 106. As illustrated in FIG. 1, the host device 104 may communicate with the storage device 106 by way of an interface 114. The host device 104 may comprise any of a wide range of devices, including computer servers, network attached storage (NAS) units, desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, and the like.

As illustrated in FIG. 1, the storage device 106 includes a controller 108, non-volatile memory (NVM) 110, volatile memory 112, and an interface 114. In some examples, the storage device 106 may include additional components not shown in FIG. 1 for sake of clarity. For example, the storage device 106 may include a printed circuit board (PCB) to which components of the storage device 106 are mechanically attached and that includes electrically conductive traces that electrically interconnect components of the storage device 106, or the like.

In some embodiments, the storage device 106 may include fewer components, for example, where one or more of the volatile memory 112 and the interface 114 are part of the controller 108. In some examples, the physical dimensions and connector configurations of the storage device 106 may conform to one or more standard form factors. Some example standard form factors of the storage device may include 3.5″ data storage device, 2.5″ data storage device, and 1.8″ data storage device. Some example standard form factors of the interface 114 may include peripheral component interconnect (PCI), PCI-extended (PCI-X), and PCI Express (PCIe) (e.g., PCIe x1, x4, x8, x16, PCIe Mini Card, MiniPCl, etc.). In some examples, the storage device 106 may be directly attached (e.g., directly soldered) to a motherboard of the host device 104.

The interface 114 of the storage device 106 may include one or both of a data bus for exchanging data with the host device 104 and a control bus for exchanging commands with the host device 104. The interface 114 may operate in accordance with any suitable protocol. For example, the interface 114 may operate in accordance with one or more of the following protocols: advanced technology attachment (ATA) (e.g., serial-ATA (SATA) and parallel-ATA (PATA)), Fibre Channel Protocol (FCP), small computer system interface (SCSI), serially attached SCSI (SAS), PCI, and PCIe, non-volatile memory express (NVMe), OpenCAPI, GenZ, Cache Coherent Interface Accelerator (CCIX), or the like. The interface 114 is communicatively connected (e.g., a data bus, a control bus, or other suitable connection) to the controller 108, allowing data to be exchanged between the host device 104 and the controller 108. In some examples, the interface 114 may also permit the storage device 106 to receive power from the host device 104.

The NVM 110 may be part of a packaged integrated circuit (IC) or other packaged silicon device, such as a memory device. The NVM 110 may also include read/write circuitry that reads data from and writes data to another portion of the memory device. For instance, the read/write circuitry of the NVM 110 may receive data and a message from the controller 108 that instructs the read/write circuitry to store the data in the NVM 110. Similarly, the read/write circuitry of the NVM 110 may receive a message from the controller 108 that instructs the read/write circuitry to retrieve data from the NVM 110. In some examples, each die (i.e., the controller 108 and memory dies making up the NVM 110 of the memory device) may be individually referred to as a silicon die. Each silicon die may include electrically conductive traces that electrically interconnect components of the silicon die, for example, non-volatile memory, or the like.

In some examples, the memory device may include any type of non-volatile memory. For example, the NVM 110 may include flash memory or any other suitable non-volatile memory. Flash memory may include NAND-based or NOR-based flash memory, and may store data based on a charge contained in a floating gate of a transistor for each flash memory cell. In NAND-based flash memory, the flash memory may be divided into a plurality of blocks that may divided into a plurality of pages. Each block of the plurality of blocks may include a plurality of NAND cells. Rows of NAND cells may be electrically connected using a word line to define a page of a plurality of pages. Respective cells in each of the plurality of pages may be electrically connected to respective bit lines. Furthermore, the NAND-based flash memory may be 2D or 3D, and may be configured as a single level cell (SLC) memory, a multi-level cell (MLC) memory, triple-level cell (TLC) memory, and/or quad-level cell (QLC) memory.

The volatile memory 112 may be used by the controller 108 to store information. The volatile memory 112 may be comprised of one or more volatile memory devices. In some examples, the controller 108 may use the volatile memory 112 as a cache. For instance, the controller 108 may store cached information in the volatile memory 112 until the cached information is written to the NVM 110. Examples of the volatile memory 112 include, but are not limited to, random-access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)).

The controller 108 manages one or more operations of the storage device 106. For instance, the controller 108 manages the reading of data from and/or the writing of data to the NVM 110. In some embodiments, when the storage device 106 receives a write command from the host device 104, the controller 108 may initiate a data storage command to store data to the NVM 110 and monitor the progress of the data storage command. In other embodiments, the controller 108 may determine at least one operational characteristic of the storage system 100 and store the at least one operational characteristic in the NVM 110.

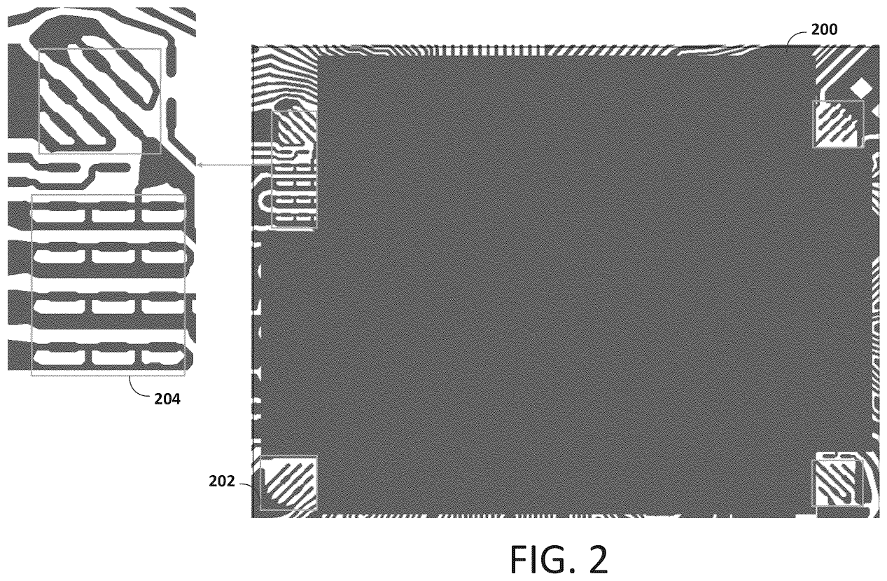

FIG. 2 is a diagram illustrating comparative straight-line traces 202 and comparative T-shaped traces 204 on a substrate 200. The comparative straight-line traces 202 includes five comparative straight traces 202 arranged diagonally at the lower left corner of the substrate 200. The comparative straight traces 202 are considered to be “linear traces” because each trace is a straight line between two contact pads that are configured to receive solder bumps of a flip chip die.

The comparative T-shaped traces 204 includes eight comparative T-shaped traces arranged horizontally near a perimeter of the substrate 200. The comparative T-shaped traces 204 are also considered to be “linear traces” because each trace also includes a straight line between two contact pads that are configured to receive solder bumps of a flip chip die.

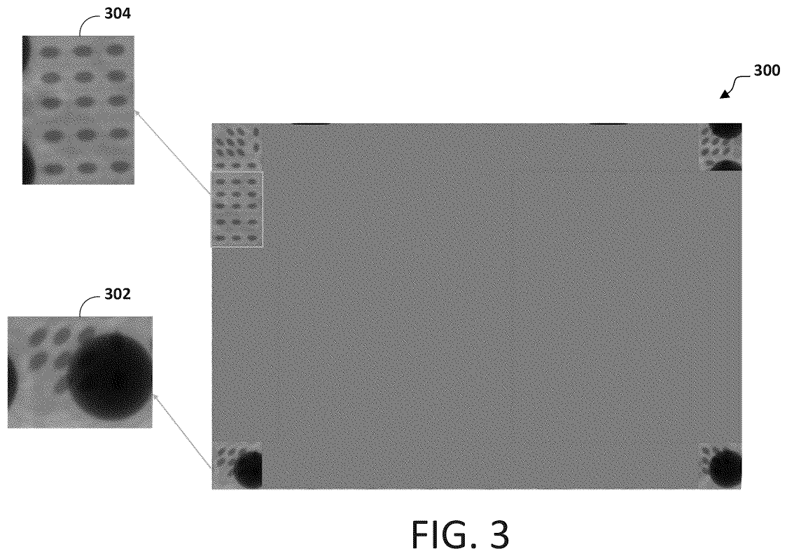

FIG. 3 is a diagram illustrating first and second portions 302 and 304 of normal high density solder bumps 300 corresponding to the comparative straight-line traces 202 and the comparative T-shaped traces 204 of FIG. 2, respectively. The first portion 302 includes six of the normal high density solder bumps 300 arranged diagonally at the corresponding corner of the substrate 200. The second portion 304 includes fifteen of the normal solder bumps 300 in three by five array with rows arranged horizontally near the perimeter of the substrate 200.

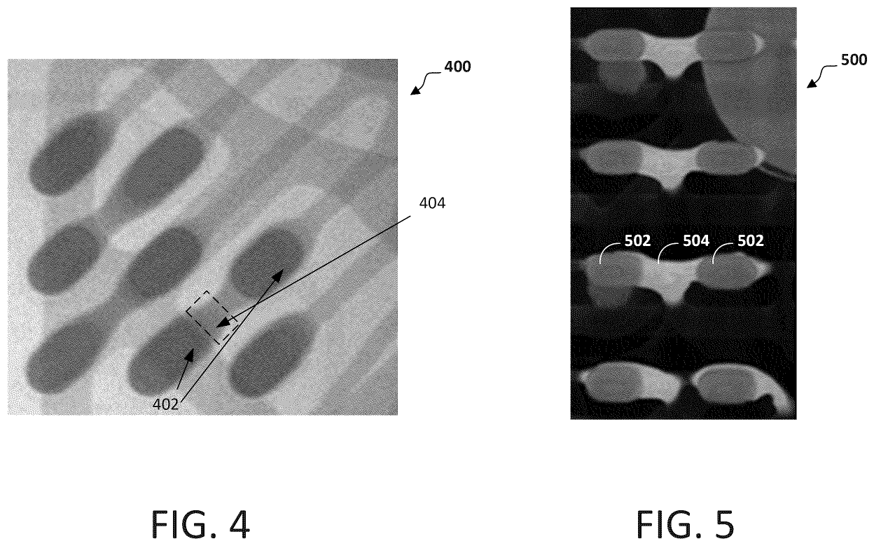

FIG. 4 is a diagram illustrating a first example 400 of a solder failure 404 of the comparative straight-line traces of FIG. 2. As illustrated in FIG. 4, the first example 400 includes two reflowed solder bumps 402 with the solder failure 404 (i.e., a solder bridge).

FIG. 5 is a diagram illustrating a second example 500 of a solder failure 504 of the comparative T-shaped traces of FIG. 2. As illustrated in FIG. 5, the second example 500 includes two reflowed solder bumps 502 with the solder failure 504 (i.e., a second solder bridge).

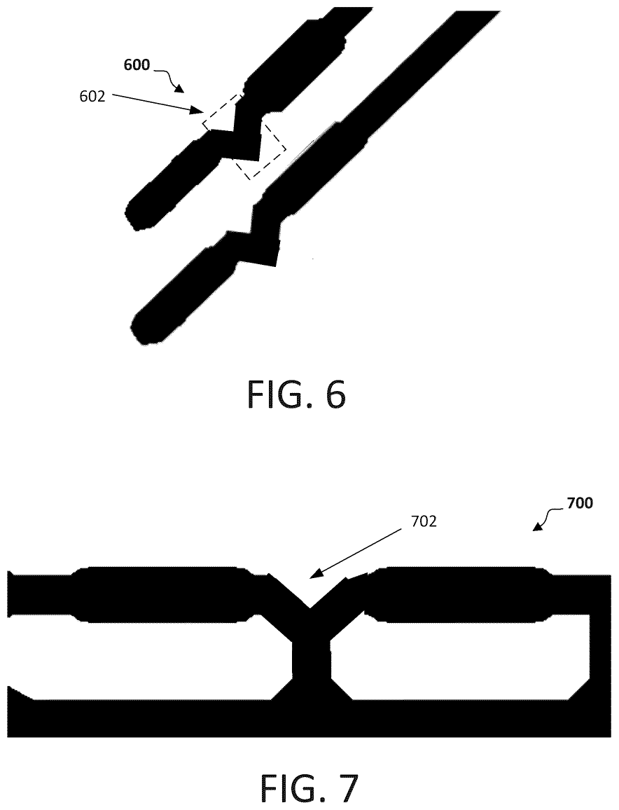

FIG. 6 is a diagram illustrating an example 600 of a V-shaped trace 602, according to various aspects of the present disclosure. The V-shaped trace 602 (i.e., a non-linear trace) addresses the solder bridge risk for a flip chip die with high bump density. Bump density is equal to a bump size (bump X size multiplied by bump Y size) multiplied by bump quantity and divided by die area. A “high” bump density means that the bump density value is greater than 14.4%. Additionally, the length of the V-shaped trace 602 is approximately forty micrometers (μm).

The V-shaped trace 602 extends the connection length between two solder bumps and causes the solder to flow in a direction away from the nearest neighboring bump. Additionally, the signal loss for the V-shaped trace 602 is negligible as the bump distance of a flip chip die with high density bumps is very small.

In some examples, the V-shaped trace 602 is used at or near an edge of a substrate for attaching a flip chip die. In other examples, the V-shaped trace 602 is used at or near a corner of a substrate for attaching a flip chip die.

FIG. 7 is a diagram illustrating an example 700 of a Y-shaped trace 702, according to various aspects of the present disclosure. The Y-shaped trace 702 (i.e., a non-linear trace) addresses the solder bridge risk for a flip chip die with high bump density. The Y-shaped trace 702 extends the connection length between the two bumps and causes the solder to flow in a direction away from the nearest neighboring bump. Additionally, the signal loss for the Y-shaped trace 702 is negligible as the bump distance of a flip chip die with high density bumps is very small. For example, the length of the Y-shaped trace 702 is approximately fifty micrometers (μm) or less.

In some examples, the Y-shaped trace 702 is used at or near an edge of a flip chip die. In other examples, the Y-shaped trace 702 is used at or near a corner of a flip chip die.

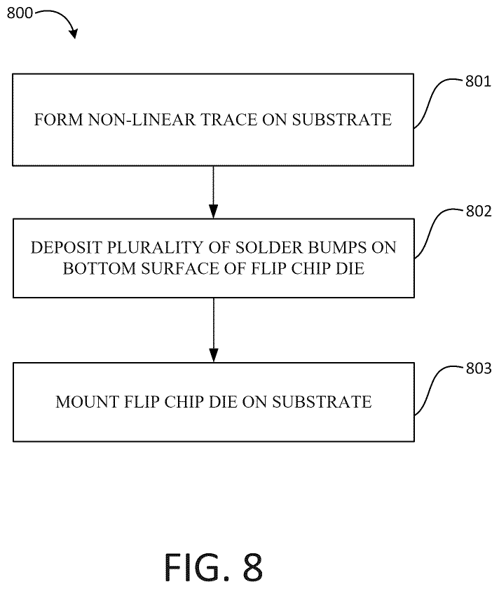

FIG. 8 is a flowchart illustrating a method of assembling a flip chip die package, according to various aspects of the present disclosure. The method 800 includes forming a non-linear trace on a substrate (at block 801). In some examples, the non-linear trace is a V-shaped trace. In other examples, the non-linear trace is a Y-shaped trace.

The method 800 includes depositing a plurality of solder bumps on bottom surface of a flip chip die (at block 802). The method 800 also includes mounting the flip chip die on the substrate (at block 803). A combined area of the plurality of solder bumps is greater than 14.4% of a die area of the flip chip die, and two or more of the plurality of solder bumps of the flip chip die are electrically connected to the non-linear trace.

The non-linear trace (i.e., V-shaped trace or Y-shaped trace) address the solder bridge risk for a flip chip die with high bump density. The non-linear bump trace designs extend the connection length between two bumps and causes the solder to flow in a direction away from the nearest neighboring bump. Additionally, the signal loss for the non-linear bump trace is negligible as the bump distance of a flip chip die with high density bumps is very small.

The following are enumerated examples of the memory devices and manufacturing methods of the present disclosure. Example 1: a flip chip die package comprising: a substrate; a flip chip die mounted on the substrate; a non-linear trace formed on the substrate; and a plurality of solder bumps attached to a bottom surface of the flip chip die, wherein a combined area of the plurality of solder bumps is greater than 14.4% of a die area of the flip chip die, and wherein a set of two or more of the plurality of solder bumps are electrically connected to the non-linear trace.
Example 2: the flip chip die package of Example 1, wherein the non-linear trace is a V-shaped trace.
Example 3: the flip chip die package of Example 1, wherein the non-linear trace is a Y-shaped trace.
Example 4: the flip chip die package of any of Examples 1-3, wherein the flip chip die further includes a second non-linear trace, and wherein a second set of two or more of the plurality of solder bumps are electrically connected to the second non-linear trace and the flip chip die.
Example 5: the flip chip die package of Example 4, wherein the non-linear trace is a V-shaped trace and the second non-linear trace is a Y-shaped trace.
Example 6: the flip chip die package of Example 4, wherein the non-linear trace is a Y-shaped trace and the second non-linear trace is a V-shaped trace.
Example 7: the flip chip die package of Example 4, wherein the non-linear trace is a first V-shaped trace and the second non-linear trace is a second V-shaped trace directly adjacent to first V-shaped trace.
Example 8: the flip chip die package of any of Examples 1-7, wherein a length of the non-linear trace is between approximately forty micrometers (μm) and fifty μm.
Example 9: the flip chip die package of any of Examples 1-8, wherein the flip chip die comprises a controller die.
Example 10: the flip chip die package of any of Examples 1-9, wherein traces located near a perimeter or a corner of the substrate that are electrically connecting together sets of two or more of the plurality of solder bumps are non-linear traces.
Example 11: a method of manufacturing a flip chip die package, the method comprising: forming a non-linear trace on a substrate; depositing a plurality of solder bumps on bottom surface of a flip chip die; and mounting the flip chip die on the substrate, wherein a combined area of the plurality of solder bumps is greater than 14.4% of a die area of the flip chip die, and wherein two or more of the plurality of solder bumps are electrically connected to the non-linear trace.
Example 12: the method of Example 11, wherein the non-linear trace is a V-shaped trace.
Example 13: the method of Example 11, wherein the non-linear trace is a Y-shaped trace.
Example 14: the method of any of Examples 11-13, further comprising: forming a second non-linear trace on the substrate, and wherein a second set of two or more of the plurality of solder bumps are electrically connected to the second non-linear trace and the flip chip die.
Example 15: the method of Example 14, wherein the non-linear trace is a V-shaped trace and the second non-linear trace is a Y-shaped trace.
Example 16: the method of Example 14, wherein the non-linear trace is a Y-shaped trace and the second non-linear trace is a V-shaped trace.
Example 17: the method of Example 14, wherein the non-linear trace is a first V-shaped trace and the second non-linear trace is a second V-shaped trace directly adjacent to first V-shaped trace.
Example 18: the method of any of Examples 11-17, wherein a length of the non-linear trace is between approximately forty micrometers (μm) and fifty μm.
Example 19: the method of any of Examples 11-18, wherein the flip chip die comprises a controller die.
Example 20: the method of any of Examples 11-19, further comprising: forming a plurality of non-linear traces at corners and along a perimeter of the substrate, wherein each of the plurality of non-linear traces electrically connects together respective sets of two or more of the plurality of solder bumps, and wherein the plurality of non-linear traces includes the non-linear trace.

The methods described above may be implemented, in some embodiments, with no extra assembling steps in the assembling process compared to prior art assembling techniques. Stated another way, the methods described herein can provide for an improved memory device without requiring longer assembling times. One or more of the above-described embodiments may allow for improved read/write speeds, improved electrical performance, more flexible use of the various dies, and the like.

While the foregoing is directed to embodiments of the present disclosure, other and further embodiments of the disclosure may be devised without departing from the basic scope thereof. The scope of the present disclosure should be determined by the following claims.

What is claimed is:

1. A flip chip die package comprising:
a substrate;
a flip chip die mounted on the substrate;
a non-linear trace formed on the substrate; and
a plurality of solder bumps attached to a bottom surface of the flip chip die,
wherein a combined area of the plurality of solder bumps is greater than 14.4% of a die area of the flip chip die, and
wherein a set of two or more of the plurality of solder bumps are electrically connected to the non-linear trace.

2. The flip chip die package of claim 1, wherein the non-linear trace is a V-shaped trace.

3. The flip chip die package of claim 1, wherein the non-linear trace is a Y-shaped trace.

4. The flip chip die package of claim 1, wherein the flip chip die further includes a second non-linear trace, and wherein a second set of two or more of the plurality of solder bumps are electrically connected to the second non-linear trace and the flip chip die.

5. The flip chip die package of claim 4, wherein the non-linear trace is a V-shaped trace and the second non-linear trace is a Y-shaped trace.

6. The flip chip die package of claim 4, wherein the non-linear trace is a Y-shaped trace and the second non-linear trace is a V-shaped trace.

7. The flip chip die package of claim 4, wherein the non-linear trace is a first V-shaped trace and the second non-linear trace is a second V-shaped trace directly adjacent to first V-shaped trace.

8. The flip chip die package of claim 1, wherein a length of the non-linear trace is between approximately forty micrometers (μm) and fifty μm.

9. The flip chip die package of claim 1, wherein the flip chip die comprises a controller die.

10. The flip chip die package of claim 1, wherein traces located near a perimeter or a corner of the substrate that are electrically connecting together sets of two or more of the plurality of solder bumps are non-linear traces.

11. A method of manufacturing a flip chip die package, the method comprising:
forming a non-linear trace on a substrate;
depositing a plurality of solder bumps on bottom surface of a flip chip die; and
mounting the flip chip die on the substrate,
wherein a combined area of the plurality of solder bumps is greater than 14.4% of a die area of the flip chip die, and
wherein two or more of the plurality of solder bumps are electrically connected to the non-linear trace.

12. The method of claim 11, wherein the non-linear trace is a V-shaped trace.

13. The method of claim 11, wherein the non-linear trace is a Y-shaped trace.

14. The method of claim 11, further comprising:
forming a second non-linear trace on the substrate, and wherein a second set of two or more of the plurality of solder bumps are electrically connected to the second non-linear trace and the flip chip die.

15. The method of claim 14, wherein the non-linear trace is a V-shaped trace and the second non-linear trace is a Y-shaped trace.

16. The method of claim 14, wherein the non-linear trace is a Y-shaped trace and the second non-linear trace is a V-shaped trace.

17. The method of claim 14, wherein the non-linear trace is a first V-shaped trace and the second non-linear trace is a second V-shaped trace directly adjacent to first V-shaped trace.

18. The method of claim 11, wherein a length of the non-linear trace is between approximately forty micrometers (μm) and fifty μm.

19. The method of claim 11, wherein the flip chip die comprises a controller die.

20. The method of claim 11, further comprising:
forming a plurality of non-linear traces at corners and along a perimeter of the substrate,
wherein each of the plurality of non-linear traces electrically connects together respective sets of two or more of the plurality of solder bumps, and
wherein the plurality of non-linear traces includes the non-linear trace.
